(19) United States
(12) Patent Application Publication
(10) Pub. No.: US 2009/0199899 A1
(43) Pub. Date: Aug. 13, 2009

(54) Photovoltaic module and method for production thereof

(76) Inventor: Peter Lechner, Vaterstetten (DE)

Correspondence Address: FLYNN THIEL BOUTELL & TANIS, P.C., 2026 RAMBLING ROAD, KALAMAZOO, MI, 49008-1631, US

(21) Appl. No.: 12/322,124

(22) Filed: Jan. 29, 2009

(30) Foreign Application Priority Data
Feb. 12, 2008 (DE) 10 2008 008 726.2

(51) Int. Cl. H01L 31/04; H01L 31/18

(52) U.S. Cl. 136/259; 438/57

(57) ABSTRACT

A photovoltaic module has on a transparent substrate (1) a transparent front electrode layer (2), a semiconductor layer (3) and a back electrode layer (4). The back electrode layer (4) has a silver layer (7) and between the silver layer (7) and the semiconductor layer (3) an interlayer (5) consisting of a doped semiconductor. A copper layer (6) is provided between the silver layer (7) and the interlayer (5).

This invention relates to a photovoltaic module according to the preamble of claim 1. It also relates to a method for producing such a module.

For photovoltaic modules having a silicon semiconductor layer, it is customary to use as a starting material a transparent substrate, for example glass, which is coated with a transparent front electrode layer, consisting for example of a transparent, electroconductive metal oxide. Then the silicon semiconductor layer and the back electrode layer are deposited. Therebetween, separating lines are produced in the layers for example with a laser, so that an integrated series connection of the individual solar cells of the module forms. Finally, the raw module is laminated with a back protection to form a finished module.

The back electrode layer used is normally a double layer comprising an interlayer and the actual metal reflector layer.

The interlayer firstly constitutes a diffusion barrier for the metal reflector layer, thus preventing metal atoms from diffusing out of the back electrode layer into the silicon layer. Due to differences in optical refractive index n and optical complex index of refraction k compared with silicon and the metal of the back electrode layer, the interlayer secondly succeeds in increasing the reflection coefficient at the silicon-metal boundary layer. For the interlayer there is used a strongly doped semiconductor, such as indium oxide (e.g. tin-doped indium oxide, ITO) or aluminum-doped zinc oxide (ZAO).

For the metal reflector layer there is used a metal film highly reflective in the visible and near infrared (NIR) light spectrum, whereby aluminum is well suited but, because of its higher reflectivity in the near infrared range, silver or else gold is even better suited. The thickness of the metal reflector layer is normally between 100 and 500 nm. Gold is therefore normally ruled out as a reflector layer for reasons of cost. An aluminum layer involves lower costs, but it has only a moderate reflection coefficient in the near infrared range.

Silver has a high reflection coefficient at reasonable costs but, unlike aluminum, a silver reflector layer has low adhesion to the interlayer. Poor adhesion of the silver reflector layer can constitute a danger to the long-term reliability of the photovoltaic module. In particular after penetration of moisture the reflector layer can delaminate from the interlayer and thus lead to failure of operation of the photovoltaic module.

To improve the adhesion of the silver reflector layer there is used in the prior art a thin layer of titanium, chromium, nickel, molybdenum, high-grade steel or tungsten added between the silver layer and the interlayer.

However, these adhesion-enhancing layers lead to a significant worsening of the reflection coefficient of the layer system with the silicon/interlayer/adhesion-enhancing layer/reflector layer interfaces.

It is therefore the object of the invention to provide for a silver reflector layer an adhesion-enhancing layer which achieves a high reflection coefficient.

This is achieved according to the invention by a copper layer being provided as an adhesion-enhancing layer between the silver layer and the interlayer consisting of the doped semiconductor.

As has been found, the inventive reflector layer has not only a high reflection coefficient of 94% and more, that is, a reflection coefficient coming very close to that of a silver layer directly on the interlayer, but also excellent adhesion to the semiconductor layer.

The silver layer can consist of pure silver or a silver alloy; this also applies to the copper layer which can consist of pure copper or a copper alloy.

The transparent substrate can be glass or another transparent material. The front electrode layer preferably consists of a transparent electrically conductive metal oxide, for example doped tin oxide, e.g. fluorine-doped tin oxide. The semiconductor layer can consist e.g. of amorphous, nanocrystalline, microcrystalline or polycrystalline silicon. Apart from silicon, it can also consist of another semiconductor, e.g. cadmium/tellurium.

The interlayer consisting of the doped semiconductor between the copper layer and the silicon layer preferably consists of a metal oxide doped with a metal. The metal oxide can be indium oxide or aluminum oxide. The metal for doping the metal oxide can be for example indium oxide or aluminum oxide. It is thus possible to use for example tin-doped indium oxide or aluminum-doped zinc oxide as the interlayer.

The layer thickness of the silver layer is preferably 50 to 500 nm, in particular 100 to 300 nm.

The layer thickness of the copper layer can be e.g. 1 to 50 nm, being preferably adjusted to 2 to 20 nm. The layer thickness of the doped semiconductor interlayer can be e.g. 10 to 300 nm, being preferably 50 to 200 nm.

The back of the silver layer, i.e. the side facing away from the copper side, can be provided with a protective layer of metal, for example with a layer of nickel or a nickel alloy. The layer thickness of the protective layer can be 10 to 400 nm, in particular 50 to 200 nm.

Moreover, it is possible to provide the back of the module with a back protection, for example with a plastic or glass layer.

The production of the inventive photovoltaic module can start with a substrate, for example a glass plate, which is coated with the front electrode layer e.g. by chemical vapor deposition (CVD). On the front electrode layer there is thereafter deposited e.g. the silicon semiconductor layer for example by chemical vapor deposition (CVD), and on the silicon semiconductor layer the back electrode layer comprising the interlayer, the copper layer and the silver layer. The back electrode layer, that is, the interlayer, the copper layer and the silver layer, can be applied for example by sputtering, as can the metal layer for back protection of the silver layer.

The photovoltaic module preferably comprises a plurality of single cells which are series-connected to each other. For series connection, the front electrode layer, the silicon semiconductor layer and the back electrode layer are provided with separating lines for example by a laser.

Hereinafter an embodiment of the inventive photovoltaic module will be explained more precisely by way of example with reference to the drawing.

Therein are shown schematically and in cross section:

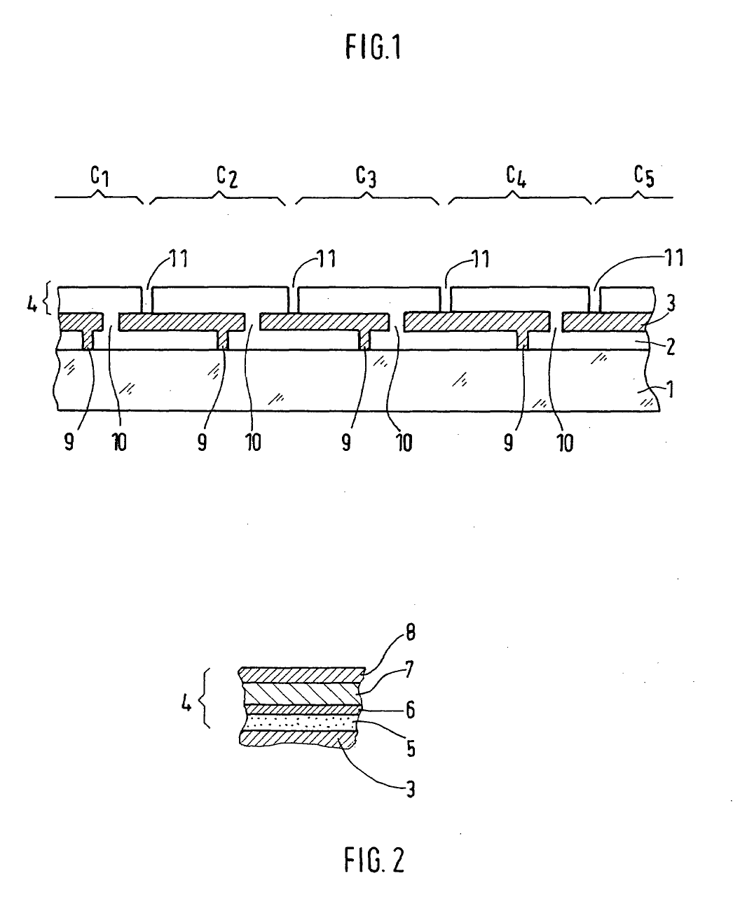

FIG. 1 a part of a photovoltaic module, and

FIG. 2 the back electrode layer in an enlarged view.

According to FIG. 1 there is provided on a large-area substrate 1, for example a glass plate, a front electrode layer 2, consisting e.g. of doped zinc oxide, to which a semiconductor layer 3 consisting e.g. of amorphous silicon is applied. The silicon semiconductor layer 3 has the back contact layer 4 applied thereto.

The module comprises single cells C1 to C5 which are series-connected. For this purpose, the front electrode layer 2 is patterned by the separating lines 9, the silicon semiconductor layer 3 by the separating lines 10, and the back electrode layer 4 by the separating lines 11. The strip-shaped single cells C1 to C5 extend perpendicular to the current flow direction F.

According to FIG. 2, the back electrode layer 4 comprises the interlayer 5 consisting of a doped semiconductor, for example aluminum-doped zinc oxide, the copper layer 6 as an adhesion-enhancing layer and the silver layer 7 as a reflector layer as well as a metal layer 8, for example a nickel layer, as a protective layer.

The following examples will serve to further explain the invention.

### EXAMPLE 1

A glass plate with a front electrode layer consisting of a transparent metal oxide and a silicon semiconductor layer was provided with a layer system comprising a 100 nm thick tin-doped indium layer (ITO), a 2 nm thick copper layer (Cu), a 200 nm thick silver layer and a 100 nm thick nickel layer (Ni). A protective layer consisting of EVA/Tedlar® was subsequently applied to the back of the sample.

The reflection coefficient of the sample at 650 nm was determined by reflectance measurement from the glass side, and further the adhesion of the silver layer was determined by pull-off test after a high-humidity and high-temperature storage (500 hours at 85° C. and 85% relative air humidity).

### EXAMPLES 2 to 4

Example 1 was repeated except that a copper layer with a thickness of 4, 8 and 12 nm was used.

### COMPARATIVE EXAMPLE 1

Example 1 was repeated except that the copper layer was omitted.

### COMPARATIVE EXAMPLES 2 and 3

Example 1 was repeated except that instead of the copper layer a 2 nm thick high-grade steel layer (SS) and a 200 nm thick aluminum layer (Al) were used, respectively.

The obtained results are rendered in the following table.

TABLE

| | | | Reflection |
|---|---|---|---|
| | | Adhesion of | coefficient at |
| | | reflector layer | 650 nm |
| Ex. 1 | 100 nm ITO/2 nm Cu/200 nm Ag/100 nm Ni | Good (+) | 95.5% |
| Ex. 2 | 100 nm ITO/4 nm Cu/200 nm Ag/100 nm Ni | Good (+) | 95.3% |
| Ex. 3 | 100 nm ITO/8 nm Cu/200 nm Ag/100 nm Ni | Good (+) | 95% |
| Ex. 4 | 100 nm ITO/12 nm Cu/200 nm Ag/100 nm Ni | Good (+) | 94.8% |
| Comp. ex. 1 | 100 nm ITO/without/200 nm Ag/100 nm Ni | Poor (−) | 97% |
| Comp. ex. 2 | 100 nm ITO/2 nm SS/200 nm Ag/100 nm Ni | Good (+) | 88% |
| Comp. ex. 3 | 100 nm ITO/200 nm Al/100 nm Ni | Very good (++) | 87% |

As can be seen here, there was determined with the inventive back electrode layer according to examples 1 to 4 not only a good adhesion of the silver layer but also a high reflection coefficient of 94.8% to 95.5%. Although the reflection coefficient is greater by about 1 to 2% according to comparative example 1 with a silver layer without a preceding copper layer, the adhesion of the silver layer is poor. In contrast, according to comparative examples 2 and 3 a good or very good adhesion of the silver layer is obtained, but only a low reflection coefficient of 87 to 88% achieved.

1. A photovoltaic module having on a transparent substrate (1) a transparent front electrode layer (2), a semiconductor layer (3) and a back electrode layer (4), said back electrode layer (4) having a silver layer (7) as a reflecting layer and between the silver layer (7) and the semiconductor layer (3) an interlayer (5) consisting of a doped semiconductor, characterized in that a copper layer (6) is provided between the silver layer (7) and the interlayer (5) consisting of the doped semiconductor.

2. The photovoltaic module according to claim 1, characterized in that the layer thickness of the silver layer (7) is 50 to 500 nm.

3. The photovoltaic module according to claim 1, characterized in that the layer thickness of the copper layer (6) is 1 to 50 nm.

4. The photovoltaic module according to claim 1, characterized in that the layer thickness of the interlayer (5) consisting of the doped semiconductor is 10 to 300 nm.

5. The photovoltaic module according to claim 1, characterized in that the doped semiconductor of which the interlayer (5) consists is a doped metal oxide.

6. The photovoltaic module according to claim 5, characterized in that the metal oxide is doped with a metal.

7. The photovoltaic module according to claim 5, characterized in that the metal oxide is indium oxide or zinc oxide.

8. The photovoltaic module according to claim 6, characterized in that the metal is tin, gallium, boron or aluminum.

9. The photovoltaic module according to claim 1, characterized in that the silver layer (7) is provided on its back with a metal layer (8) as a protective layer.

10. The photovoltaic module according to claim 9, characterized in that the metal layer (8) is a nickel layer.

11. The photovoltaic module according to claim 1, characterized in that the semiconductor layer (3) consists of silicon.

12. A method for producing a photovoltaic module according to claim 1, characterized in that the interlayer (5) consisting of the doped semiconductor, the copper layer (6) and/or the silver layer (7) are applied by sputtering.
